(19) United States
(12) Patent Application Publication
(10) Pub. No.: US 2003/0085745 A1
(43) Pub. Date: May 8, 2003

(54) PMOS/NMOS circuits

(76) Inventors: Siva G. Narendra, Beaverton, OR (US); Vivek K. De, Beaverton, OR (US)

Correspondence Address: FISH & RICHARDSON, PC, 4350 LA JOLLA VILLAGE DRIVE, SUITE 500, SAN DIEGO, CA, 92122, US

(21) Appl. No.: 10/008,532

(22) Filed: Nov. 5, 2001

(51) Int. Cl. H03K 3/017

(52) U.S. Cl. 327/175

(57) ABSTRACT

Signals are sent through a CMOS circuit that has PMOS and NMOS elements, and equal (in some cases constant) charging and discharging currents are applied to the CMOS circuit so that it is insensitive to fabrication process variations.

### BACKGROUND

This invention relates to PMOS/NMOS circuits.

For example, in some high performance CMOS gates of the kind used for clock distribution or multi-phase clock generation, a CMOS inverter is followed (in close proximity on the fabricated device) by another CMOS inverter. This arrangement reduces the skewing of drive currents that would result from the lack of correlation in threshold voltage differences for the PMOS and NMOS elements in a set of fabricated devices. The rising and falling edges of clock signals pass through both inverters, one after the other, so that the skew between the NMOS and PMOS elements does not degrade the duty cycle of the clock.

### DESCRIPTION

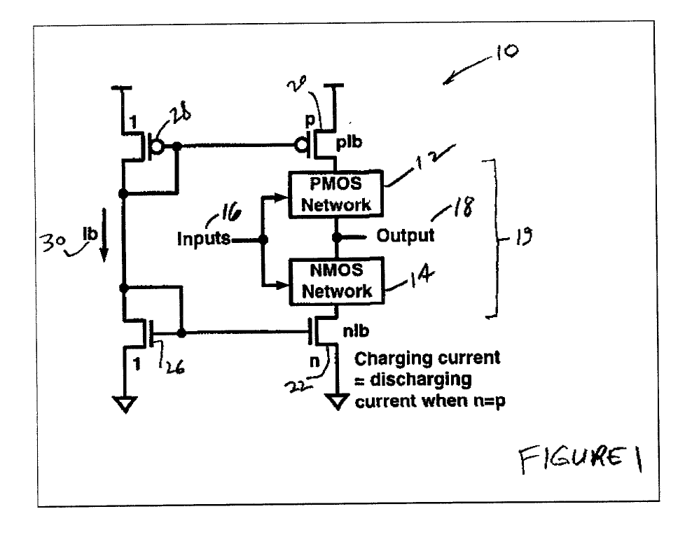

(FIGS. 1, 2, 3, and 5 are circuit diagrams.

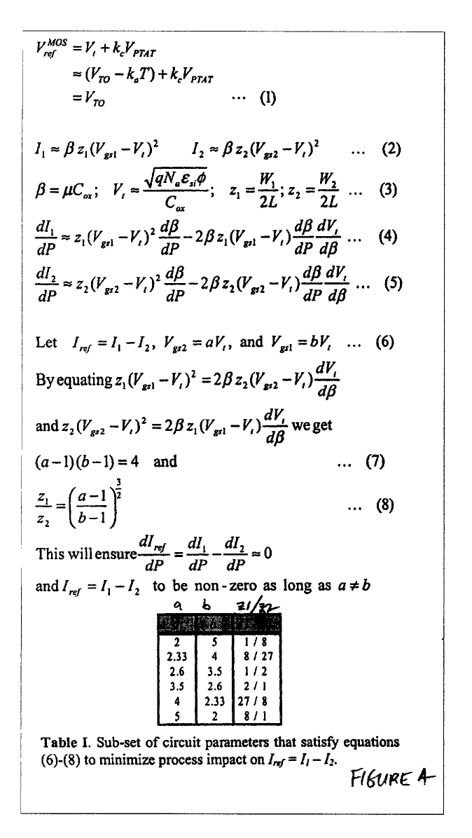

FIG. 4 shows equations.)

As shown in FIG. 1, a PMOS network 12 and an NMOS network 14 are both part of a computational block 19 formed on a fabricated device. The PMOS and NMOS networks may comprise a single inverter that is useful, for example, in clock drivers, digital voltage sampling circuits, repeaters, single-phase to two-phase clock generation logic, or any other CMOS gate that requires a preset switching threshold.

Incoming signals to the inverter device are delivered from input line 16 to the PMOS and NMOS networks. The output signals of the networks are fed to an output line 18. By appropriate arrangements the charging and discharging currents can be made to be always equal, which renders the inverter insensitive to variations in threshold voltages for NMOS and CMOS elements that occur among multiple units of the fabricated devices.

The charging and discharging currents for the inverter are provided respectively by the PMOS and NMOS devices 20 and 22. To keep the charging and discharging currents equal notwithstanding process variations, the effect of process variations on the NMOS and PMOS devices are sensed using nearby PMOS and NMOS devices 28, 26, which carry a bias current Ib 30. The bias current causes the gate-to-source voltage Vgs of each of the devices 26 and 28 to be at values such that the currents flowing through the PMOS and NMOS elements are the same. Because the gates of elements 28 and 20 are connected, and the gates of elements 26 and 22 are connected, Vgs is the same for both of the NMOS devices and Vgs is the same for both of the PMOS devices. The result is that the charging and discharging currents on the computational block 19 are equal.

While the arrangement of FIG. 1 provides equal charging and discharging currents and therefore equal delays, it does not guarantee that the delays will be the same across multiple fabricated devices that exhibit different threshold voltages.

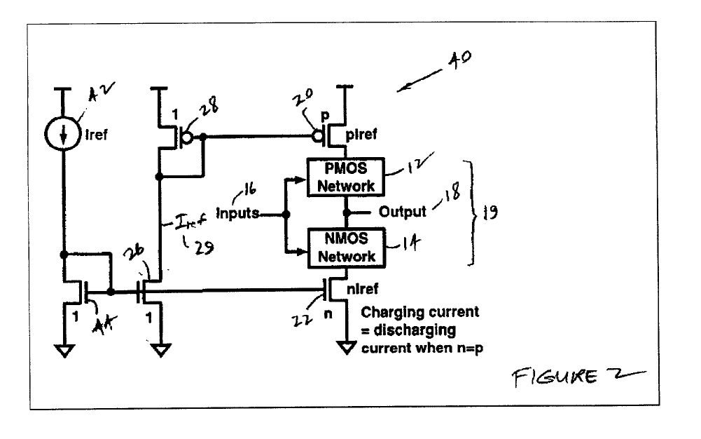

As shown in FIG. 2, an inverter circuit 40 that is insensitive both to skew differences and to threshold voltage differences among processed devices includes elements that provide charging and discharging currents that are both equal and constant across fabricated devices.

In the circuit of FIG. 2, elements 26 and 44 form a current mirror so that the current flowing through device 44 is the same as the current flowing through device 26. The current Iref flowing through device 26 is controlled by a constant current source that is insensitive to processes variations. Because the gates of devices 22 and 44 are connected, the discharging current provided by device 22 will be equal to Iref. Also, because the gates of devices 20, 28 are connected, the charging current provide by device 20 will also equal Iref.

Among the benefits of the invention are the ability to produce more accurate designs of circuits that depend on proper PMOS and NMOS skews, for example, clock drivers and digital voltage sampling circuits. This will be especially useful as technology scales to smaller and smaller feature sizes, making process variations in finished devices even more significant.

Constant Current Reference

The constant current reference of FIG. 2 can be provided by a process-compensated MOS current generation technique that does not require a reference voltage. The technique exhibits reduced sensitivity to variations in process parameters including gate oxide thickness and the resulting threshold voltage.

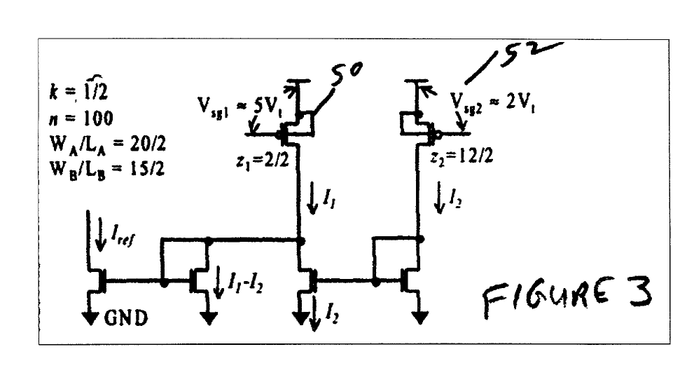

As shown in FIG. 3, the idea behind process compensated current, Iref, is to use the natural variations of the saturation currents, I1 and I2, of two MOSFET devices 50, 52, to cancel variations in the difference of the two currents, i.e., variations in Iref=I1−I2. The result is a constant current source Iref.

Long-channel wide-width MOSFET devices are used to minimize process variations related to small lateral dimensions.

In FIG. 4, equations (2) and (3) define the saturation currents 11 and 12. (Inventor—please define each of the variables that appears in the equations.). Assume that the elements that generate 11 and 12 are laid out in the fabricated device to have proper matching. Process parameters that are expected to impact the magnitudes of currents 11 and 12 are β and Vt.

Equations (4) and (5) of FIG. 4 show the changes in the two currents, 11 and 12, with respect to process (P) for MOSFET devices operating in the saturation region, assuming mobility is not a strong function of channel doping.

To achieve a non-zero process compensated current, Iref, circuit parameters are set such that the dβ/dP term of one current is canceled by the dVt/dP term of the other current, so that the change in Iref with process variations, dIref/dP=dI1/dP−dI2/dP, will be zero, but Iref=I1−I2 will be non-zero. The necessary and sufficient conditions to achieve process compensation for Iref are given by equations (6), (7) and (8). The table I at the bottom of FIG. 4 shows a possible set of values for the circuit parameters a, b, and z1/z2 that satisfy equations (6)-(8).

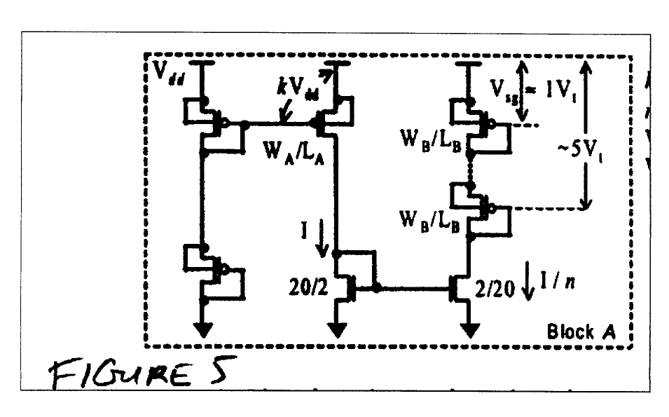

The circuit used to generate process compensated Iref for the example in which a=2 and b=5 is depicted in FIG. 3. Block A in FIG. 5 illustrates a method for generation of aVt and βVt voltages. Because it is not possible to accurately generate Vt, the current reference device size ratio z1/z2 was optimized for minimizing variation in Iref.

Other implementations are within the scope of the following claims.

1. Apparatus comprising
a CMOS circuit having PMOS and NMOS elements that are connected to receive an input signal and to deliver an output signal, and
charge/discharge circuitry configured to deliver equal charging and discharging currents to the CMOS circuit.

2. The apparatus of claim 1 in which the charge/discharge circuitry includes a PMOS discharging element and an NMOS charging element.

3. The apparatus of claim 2 in which the charge/discharge circuitry includes an equalizing leg that includes PMOS and NMOS sensing elements connected in series, the PMOS sensing element being connected to the PMOS discharging element, and the NMOS sensing element being connected to the NMOS charging element.

4. The apparatus of claim 3 in which the gate-to-source voltages of the PMOS and NMOS sensing and discharging elements are connected to be kept equal.

5. The apparatus of claim 2 in which the charge/discharge circuitry are driven by a constant current source.

6. The apparatus of claim 5 in which the constant current source is coupled to the charge/discharge circuitry through a current mirror.

7. The apparatus of claim 5 in which the constant current source is derived as a difference of currents flowing in two MOSFET devices.

8. The apparatus of claim 1 in which the CMOS circuit comprises an inverter.

9. The apparatus of claim 1 in which the CMOS circuit comprises one of a clock driver, a digital voltage sampling circuit, a repeaters, or a single-phase to two-phase clock generation logic.

10. A clocking circuit comprising
a single inverter including PMOS and NMOS elements fabricated on a CMOS device, and
charge/discharge circuitry configured to deliver equal charging and discharging currents to the CMOS circuit.

11. The apparatus of claim 1 in which the charge/discharge circuitry includes a PMOS discharging element and an NMOS charging element.

12. A method comprising
sending signals through a CMOS circuit that has PMOS and NMOS elements, and
delivering equal charging and discharging currents to the CMOS circuit.

13. The method of claim 12 including sensing characteristics of the operation of the CMOS and NMOS elements and causing the charging and discharging currents to be equal in response to the sensed characteristics.

14. The method of claim 12 including driving the charging and discharging from a constant current source.

15. The method of claim 14 including coupling the constant current source to the charge/discharge circuitry through a current mirror.

16. The method of claim 15 including deriving the constant current source as a difference of currents flowing in two MOSFET devices.
